(19) United States
(12) Patent Application Publication
(10) Pub. No.: US 2025/0386733 A1
(43) Pub. Date: Dec. 18, 2025

(54) PIEZOELECTRIC ELEMENT

(71) Applicant: TDK CORPORATION, Tokyo (JP)

(72) Inventors: Kazuki SAITO, Tokyo (JP); Kaoru KIJIMA, Tokyo (JP); Akira SATOH, Tokyo (JP); Toma SASAKI, Tokyo (JP)

(73) Assignee: TDK CORPORATION, Tokyo (JP)

(21) Appl. No.: 19/213,332

(22) Filed: May 20, 2025

(30) Foreign Application Priority Data
Jun. 12, 2024 (JP) 2024-095395

(51) Int. Cl. H10N 30/87; H10N 30/072; H10N 30/50; H10N 30/853

(52) U.S. Cl. CPC H10N 30/871; H10N 30/072; H10N 30/50; H10N 30/853; H10N 30/874

(57) ABSTRACT

A piezoelectric element includes a piezoelectric body. The piezoelectric body includes a first region including a first main surface and a second region including a second main surface opposing the first main surface. The piezoelectric element includes a first internal electrode group in the first region and a second internal electrode group in the second region. Each of the first internal electrode group and the second internal electrode group includes a plurality of internal electrodes opposing each other in a direction in which the first main surface and the second main surface oppose each other. The internal electrode, among the plurality of internal electrodes of the first internal electrode group, closest to the second region and the internal electrode, among the plurality of internal electrodes of the second internal electrode group, closest to the first region are electrically connected to each other.

### CROSS-REFERENCE TO RELATED APPLICATIONS

This application is based upon and claims the benefit of priority from Japanese Patent Application No. 2024-095395, filed on Jun. 12, 2024, the entire contents of which are incorporated herein by reference.

### BACKGROUND

### Field

The present disclosure relates to a piezoelectric element.

### Description of the Related Art

Known piezoelectric elements include one electrode and two piezoelectric elements on the both side of the one electrode (see, for example, Japanese Unexamined Patent Publication No. 2005-318725). Each of the two piezoelectric elements is configured to be displaced in response to applying electrical voltage.

### SUMMARY

An object of aspects of the present disclosure is to provide a piezoelectric element capable of reducing stress generated in a piezoelectric body.

A piezoelectric element according to one aspect of the present disclosure includes a piezoelectric body, a first internal electrode group, and a second internal electrode group. The piezoelectric body includes a first main surface and a second main surface opposing each other and a side surface coupling the first main surface and the second main surface, and includes a first region including the first main surface and a second region including the second main surface. The first internal electrode group is disposed in the first region, and includes a plurality of internal electrodes opposing each other in a direction in which the first main surface and the second main surface oppose each other. The second internal electrode group disposed in the second region, and includes a plurality of internal electrodes opposing each other in a direction in which the first main surface and the second main surface oppose each other. An internal electrode, among the plurality of internal electrodes included in the first internal electrode group, closest to the second region and an internal electrode, among the plurality of internal electrodes included in the second internal electrode group, closest to the first region are electrically connected to each other.

In the one aspect described above, the first internal electrode group includes the plurality of internal electrodes opposing each other in the first region, and the first region includes a region positioned between the plurality of internal electrodes opposing each other. The second internal electrode group includes the plurality of internal electrodes opposing each other in the second region, and the second region includes a region positioned between the plurality of internal electrodes opposing each other. Hereinafter, a region positioned between the plurality of internal electrodes opposing each other may be referred to as an “inter-electrode region”.

When applying electrical voltage, an electric field is generated in the inter-electrode region included in each of the first and second regions, and the inter-electrode region included in each of the first and second regions can be displaced. In the one aspect described above, the internal electrode closest to the second region and the internal electrode closest to the first region are electrically connected. Therefore, when applying the electrical voltage, the electric field tends to not be generated in a region positioned between the internal electrode closest to the second region and the internal electrode closest to the first region, that is, a region positioned between the first region and the second region, and the region positioned between the first region and the second region tends not to be displaced. When the inter-electrode region included in each of the first region and the second region is displaced, stress may act on the second region due to displacement in the first region, and stress may act on the first region due to displacement in the second region. However, the region positioned between the first region and the second region reduces the stress acting on the second region, and reduces the stress acting on the first region. The one aspect described above can reduce stress generated in the piezoelectric body.

A piezoelectric element according to another aspect of the present disclosure includes a piezoelectric body, a first internal electrode group, a second internal electrode group, and an internal conductor. The piezoelectric body includes a first main surface and a second main surface opposing each other and a side surface coupling the first main surface and the second main surface, and includes a first region including the first main surface and a second region including the second main surface. The first internal electrode group is disposed in the first region, and includes a plurality of internal electrodes opposing each other in a direction in which the first main surface and the second main surface oppose each other. The second internal electrode group is disposed in the second region, and includes a plurality of internal electrodes opposing each other in a direction in which the first main surface and the second main surface oppose each other. The internal conductor is disposed between an internal electrode, among the plurality of internal electrodes included in the first internal electrode group, closest to the second region and an internal electrode, among the plurality of internal electrodes included in the second internal electrode group, closest to the first region, and is not electrically connected to the plurality of internal electrodes included in the first internal electrode group and the plurality of internal electrodes included in the second internal electrode group.

In the other aspect described above, the piezoelectric body a region positioned between the internal electrode, among the plurality of internal electrodes included in the first internal electrode group, closest to the second region and the internal electrode, among the plurality of internal electrodes included in the second internal electrode group, closest to the first region, that is, between the first region and the second region. In the other aspect described above, the internal conductor is disposed in the region positioned between the first region and the second region, and is not electrically connected to the plurality of internal electrodes included in the first internal electrode group and the plurality of internal electrodes included in the second internal electrode group. Therefore, when applying electrical voltage, an electric field tends to not be generated in the region positioned between the first region and the second region. The region positioned between the first region and the second region tends not to be displaced. Stress may act on the second region due to displacement in the first region when the first region is displaced, and stress may act on the first region due to displacement in the second region when the second region is displaced. However, the region positioned between the first region and the second region reduces the stress acting on the second region, and reduces the stress acting on the first region. The other aspect described above can reduce stress generated in the piezoelectric body.

### BRIEF DESCRIPTION OF THE DRAWINGS

FIG. 1 is a perspective view illustrating a vibration device with a piezoelectric element according to an example;

FIG. 2 is a view illustrating a cross-sectional configuration of the piezoelectric element according to the example;

FIG. 3 is an exploded perspective view illustrating the piezoelectric element according to the example;

FIG. 4 is an exploded perspective view illustrating the piezoelectric element according to the example;

FIG. 5 is an exploded perspective view illustrating the piezoelectric element according to the example;

FIG. 6 is a view illustrating a cross-sectional configuration of a piezoelectric element according to a modified example of the example;

FIG. 7 is an exploded perspective view illustrating the piezoelectric element according to the modified example of the example; and

FIG. 8 is a view illustrating a cross-sectional configuration of a piezoelectric element according to another example.

### DETAILED DESCRIPTION

Hereinafter, examples of the present disclosure will be described in detail with reference to the accompanying drawings. In the following description, the same components or components having the same functions are denoted with the same reference numerals and overlapped explanation is omitted.

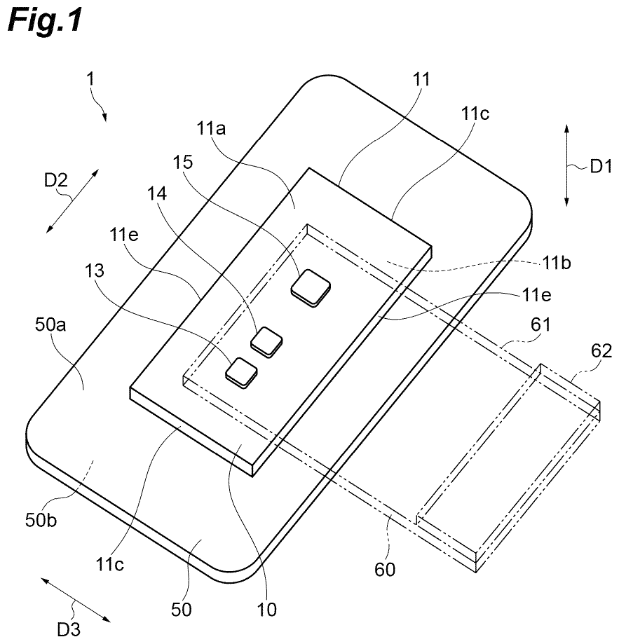

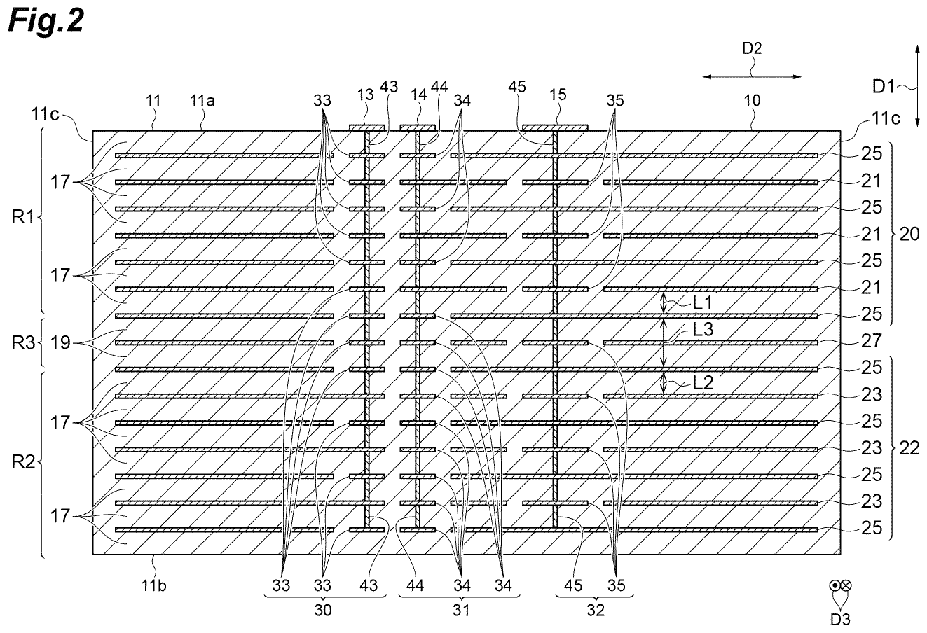

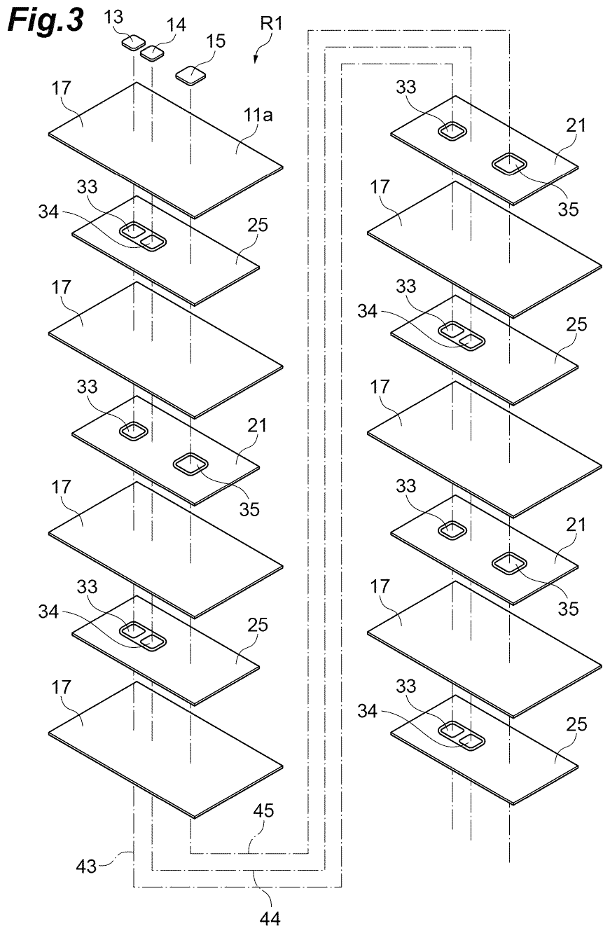

A configuration of a piezoelectric element 10 according to the example will be described with reference to FIGS. 1 to 5. FIG. 1 is a perspective view illustrating a vibration device with a piezoelectric element according to an example. FIG. 2 is a view illustrating a cross-sectional configuration of the piezoelectric element according to the example. FIGS. 3, 4, and 5 are exploded perspective views illustrating the piezoelectric element according to the example.

As illustrated in FIG. 1, a vibration device 1 includes the piezoelectric element 10, a vibration member 50, and a wiring member 60. In FIG. 1, the wiring member 60 is illustrated with a long dashed double-short dashed line in order to clearly illustrate the piezoelectric element 10.

A configuration of the piezoelectric element 10 will be described. The piezoelectric element 10 includes a piezoelectric body 11, a plurality of external electrodes 13, 14, and 15, and a plurality of connection conductors 30, 31, and 32. For example, the piezoelectric element 10 includes three external electrodes 13, 14, and 15 and three connection conductors 30, 31, and 32. The connection conductor 30 is connected to the external electrode 13. The connection conductor 31 is connected to the external electrode 14. The connection conductor 32 is connected to the external electrode 15. The piezoelectric element 10 includes a bimorph piezoelectric element.

The piezoelectric body 11 has a rectangular parallelepiped shape. The rectangular parallelepiped shape includes, for example, a rectangular parallelepiped shape in which corners and ridges are chamfered, or a rectangular parallelepiped shape in which the corners and ridges are rounded. The piezoelectric body 11 includes a main surface 11a and a main surface 11b opposing each other, a pair of side surfaces 11c opposing each other, and a pair of side surfaces 11e opposing each other.

The main surfaces 11a and 11b oppose each other in a first direction D1. The main surfaces 11a and 11b are perpendicular to the first direction D1. The pair of side surfaces 11c oppose each other in a second direction D2. The pair of side surfaces 11e oppose each other in a third direction D3. The pair of side surfaces 11c and the pair of side surfaces 11e extend in the first direction D1 to couple the pair of main surfaces 11a and 11b. The pair of side surfaces 11c and the pair of side surfaces 11e are adjacent to each other. For example, a surface of the piezoelectric body 11 includes the main surfaces 11a and 11b and the side surfaces 11c and 11e.

The main surfaces 11a and 11b, the pair of side surfaces 11c, and the pair of side surfaces 11e have a rectangular shape. The rectangular shape includes, for example, a rectangular shape in which corners are chamfered or a rectangular shape in which corners are rounded. The main surface 11a may include a first main surface, and the main surface 11b may include a second main surface.

A length of the piezoelectric body 11 in the first direction D1 is, for example, 0.3 to 2 mm. A length of the piezoelectric body 11 in the second direction D2 is, for example, 5 to 70 mm. A length of the piezoelectric body 11 in the third direction D3 is, for example, 5 to 70 mm. In the piezoelectric body 11, for example, the second direction D2 includes a longitudinal direction. The second direction D2 intersects the first direction D1. The third direction D3 intersects the first direction D1 and the second direction D2. For example, the first direction D1, the second direction D2, and the third direction D3 are perpendicular to each other.

The external electrodes 13, 14, and 15 are disposed on the main surface 11a. The external electrodes 13, 14, and 15 are disposed in the second direction D2 in the order of the external electrode 13, the external electrode 14, the external electrode 15. The external electrodes 13 and 14 are adjacent to each other in the second direction D2. The external electrodes 14 and 15 are adjacent to each other in the second direction D2. In the second direction D2, a shortest distance between the external electrodes 14 and 15 is, for example, longer than a shortest distance between the external electrodes 13 and 14. The external electrode 13, 14, and 15 is separated from the side surfaces 11c and 11e when viewed from the first direction D1.

The external electrodes 13, 14, and 15 have a rectangular shape. For example, the external electrodes 13, 14, and 15 have a rectangular shape in which corners are rounded. The external electrodes 13, 14, and 15 may have a square shape. The external electrodes 13, 14, and 15 include an electrically conductive material. The electrically conductive material includes, for example, Ag, Pd, Pt, or an Ag—Pd alloy. The external electrodes 13, 14, and 15 are configured, for example, as a sintered body of electrically conductive paste containing the electrically conductive material.

As illustrated in FIGS. 2 to 5, the piezoelectric body 11 includes a region R1 and a region R2. The region R1 includes the main surface 11a, and the region R2 includes the main surface 11b. The region R1 is positioned closer to the main surface 11a, and the region R2 is positioned closer to the main surface 11b. The regions R1 and R2 are separated from each other in the first direction D1. For example, the piezoelectric body 11 includes a region R3. The region R3 is positioned between the regions R1 and R2 in the first direction D1. The region R3 does not include the main surfaces 11a and 11b. The region R1 may include a first region, and the region R2 may include a second region.

The piezoelectric body 11 includes a plurality of piezoelectric layers 17. The plurality of piezoelectric layers 17 are laminated in the first direction D1. Each of the regions R1 and R2 includes a plurality of piezoelectric layers 17. The region R1 includes, for example, seven piezoelectric layers 17. The region R2 includes, for example, seven piezoelectric layers 17. The piezoelectric layer 17, among the piezoelectric layers 17 included in the region R1, closest to the main surface 11a includes the main surface 11a. The piezoelectric layer 17, among the piezoelectric layers 17 included in the region R2, closest to the main surface 11b includes the main surface 11b. In the regions R1 and R2, the piezoelectric layers 17 are polarized. The piezoelectric layers 17 with opposite polarization directions are alternately disposed in the first direction D1. For example, the plurality of piezoelectric layers 17 have the same thickness. In this specification, “same” does not necessarily mean only that values are identical. Even in the case in which a slight difference in a predetermined range, a manufacturing error, or a measurement error is included, it can be defined that values are the same to each other. For example, in the case in which each of values falls within a range of ±10% of an average value of the values, the values are defined to be the same to each other.

A piezoelectric element 10 includes an internal electrode group 20 and an internal electrode group 22. The internal electrode group 20 and the internal electrode group 22 are separated from each other in the first direction D1.

The internal electrode group 20 is disposed in the region R1. As illustrated in FIGS. 2 and 3, the internal electrode group 20 includes a plurality of internal electrodes 21 and 25. The internal electrode 25 opposes the internal electrode 21. The plurality of internal electrodes 21 and 25 oppose each other in the first direction D1. The internal electrodes 21 and 25 are disposed in different positions (layers) in the first direction D1. For example, the internal electrode group 20 includes three internal electrodes 21 and four internal electrodes 25. In the internal electrode group 20, the internal electrodes 21 and the internal electrodes 25 are alternately disposed, and the internal electrodes 21 and the internal electrodes 25 oppose each other with a corresponding piezoelectric layer 17 of the plurality of piezoelectric layers 17 interposed therebetween and are separated by a distance L1. The distances L1 between the internal electrodes 21 and the internal electrodes 25 are the same. FIG. 3 illustrates a configuration of the region R1.

The internal electrode group 20 includes the internal electrode 25, among the plurality of internal electrodes 21 and 25 included in the internal electrode group 20, closest to the region R2. The internal electrode group 20 includes the internal electrode 25, among the plurality of internal electrodes 21 and 25 included in the internal electrode group 20, closest to the main surface 11a.

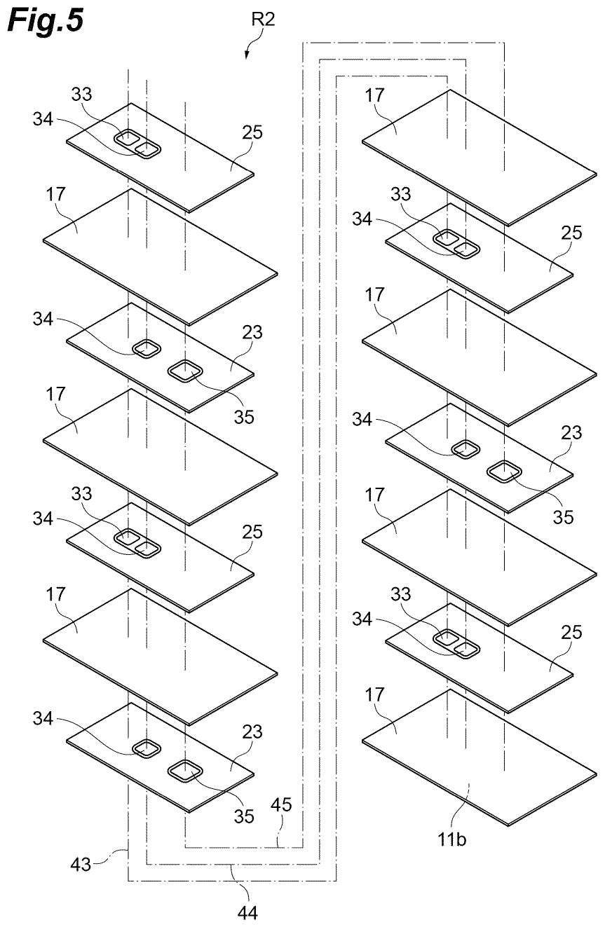

The internal electrode group 22 is disposed in the region R2. As illustrated in FIGS. 2 and 5, the internal electrode group 22 includes a plurality of internal electrodes 23 and 25. The internal electrodes 23 are not electrically connected to the plurality of internal electrodes 21 and 25 included in the internal electrode group 20. The internal electrode 25 opposes the internal electrode 23. The plurality of internal electrodes 23 and 25 oppose each other in the first direction D1. The internal electrodes 25 included in the internal electrode group 22 are electrically connected to the internal electrodes 25 included in the internal electrode group 20. The internal electrodes 23 and 25 are disposed in different positions (layers) in the first direction D1. For example, the internal electrode group 22 includes three internal electrodes 23 and four internal electrodes 25. In the internal electrode group 22, the internal electrodes 22 and the internal electrodes 25 are alternately disposed, and the internal electrodes 23 and the internal electrodes 25 oppose each other with a corresponding piezoelectric layer 17 of the plurality of piezoelectric layers 17 interposed therebetween and separated by a distance L2. The distances L2 between the internal electrodes 23 and the internal electrodes 25 are the same. FIG. 5 illustrates a configuration of the region R2.

The internal electrode group 22 includes the internal electrode 25, among the plurality of internal electrodes 23 and 25 included in the internal electrode group 22, closest to the region R1. The internal electrode group 22 includes the internal electrode 25, among the plurality of internal electrodes 23 and 25 included in the internal electrode group 22, closest to the main surface 11b.

The internal electrode 25, among the plurality of internal electrodes 23 and 25 included in the internal electrode group 22, closest to the region R1 and the internal electrode 25, among the plurality of internal electrodes 21 and 25 included in the internal electrode group 20, closest to the region R2 are electrically connected to each other.

The internal electrode group 20 may include a first internal electrode group, and the internal electrode group 22 may include a second internal electrode group. The internal electrode 21 may include a first internal electrode, and the internal electrode 25 included in the internal electrode group 20 may include a second internal electrode. The internal electrode 23 may include a third internal electrode, and the internal electrode 25 included in the internal electrode group 22 may include a fourth internal electrode.

In the internal electrode groups 20 and 22, the internal electrodes 21, 23, and 25 are not exposed on the surface of the piezoelectric body 11. The internal electrodes 21, 23, and 25 are not exposed to the main surface 11a, the main surface 11b, and the side surfaces 11c and 11e. The internal electrodes 21, 23, and 25 are separated from the main surface 11a, the main surface 11b, and the side surfaces 11c and 11e.

The region R3 is positioned between the internal electrode 25, among the internal electrode group 20, closest to the region R2 and the internal electrode 25, among the internal electrode group 22, closest to the region R1. The region R3 includes a plurality of piezoelectric layers 19. The region R3 includes, for example, two piezoelectric layers 19. The piezoelectric layer 19 is positioned between the piezoelectric layer 17 included in the region R1 and the piezoelectric layer 17 included in the region R2. In the piezoelectric body 11, the plurality of piezoelectric layers 17 and 19 are laminated in the first direction D1. Each of the piezoelectric layers 19 has the same thickness. The piezoelectric layer 19 is substantially unpolarized.

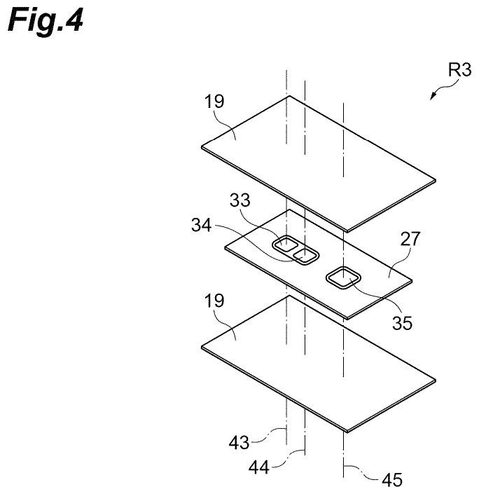

As illustrated in FIGS. 2 and 4, the piezoelectric element 10 includes an internal conductor 27. The internal conductor 27 is disposed in the region R3. The piezoelectric element 10 includes, for example, one internal conductor 27. The internal conductor 27 is not electrically connected to the plurality of internal electrodes 21 and 25 included in the internal electrode group 20 and the plurality of internal electrodes 23 and 25 included in the internal electrode group 22. The internal conductor 27 is not exposed on the surface of the piezoelectric body 11. The internal conductor 27 is not exposed to the side surfaces 11c and 11e. The internal conductor 27 is separated from the side surfaces 11c and 11e. FIG. 4 illustrates a configuration of the region R3.

The internal conductor 27 is positioned between the internal electrode 25, among the internal electrode group 20, closest to the region R2 and the internal electrode 25, among the internal electrode group 22, closest to the region R1. The internal conductor 27 is positioned in the region R3. The internal electrode 25 closest to the region R2 and the internal electrode 25 closest to the region R1 are separated from each other by a distance L3 in the first direction D1. The distance L3 corresponds to a length of the region R3 in the first direction D1. The distance L3 is larger than the distance L1 and the distance L2. The piezoelectric element 10 may not include the internal conductor 27. Even in a configuration in which the piezoelectric element 10 does not include the internal conductor 27, the distance L3 is larger than the distance L1 and the distance L2.

The piezoelectric layers 17 and 19 includes a piezoelectric material. The piezoelectric layers 17 and 19 includes, for example, a piezoelectric ceramic material. The piezoelectric ceramic material includes, for example, PZT [Pb (Zr, Ti)O₃], PT (PbTiO₃), PLZT [(Pb, La) (Zr, Ti)O₃], or barium titanate (BaTiO₃). Each of the piezoelectric layers 17 and 19 includes, for example, a sintered body of a ceramic green sheet containing the piezoelectric ceramic material described above. In the actual piezoelectric body 11, the piezoelectric layers 17 and 19 are integrated to such an extent that a boundary between the piezoelectric layers 17 and 19 cannot be visually recognized.

The internal electrodes 21 disposed in the region R1 are electrically connected to the external electrodes 14 via the connection conductor 31. The connection conductor 31 includes a plurality of conductors 34 and a plurality of through-hole conductors 44.

In the region R1, each of the plurality of conductors 34 is positioned in the same layer as a corresponding internal electrode 25 of the plurality of internal electrodes 25. Each of the plurality of conductors 34 is positioned in an opening formed in the corresponding internal electrode 25. Each opening is formed at a position corresponding to the external electrode 14 when viewed from the first direction D1. Each of the plurality of conductors 34 is surrounded by the corresponding internal electrode 25 when viewed from the first direction D1. Each of the plurality of conductors 34 is separated from the corresponding internal electrode 25. Each of the plurality of conductors 34 opposes the external electrode 14 in the first direction D1, and is disposed at a position overlapping the external electrode 14 when viewed from the first direction D1. Each of the plurality of conductors 34 opposes a corresponding internal electrode 21 of the plurality of internal electrodes 21 in the first direction D1, and is disposed at a position overlapping the internal electrodes 21 when viewed from the first direction D1.

In the region R2, each of the plurality of conductors 34 is positioned in the same layer as a corresponding internal electrode 23 of the plurality of internal electrodes 23 or a corresponding internal electrode 25 of the plurality of internal electrodes 25. Each of the plurality of conductors 34 is positioned in an opening formed in the corresponding internal electrode 23 or an opening formed in the corresponding internal electrode 25. Each opening is formed at a position corresponding to the external electrode 14 when viewed from the first direction D1. Each of the plurality of conductors 34 is surrounded by the corresponding internal electrode 23 or the corresponding internal electrode 25 when viewed from the first direction D1. Each of the plurality of conductors 34 is separated from the corresponding internal electrode 23 or the corresponding internal electrode 25. Each of the plurality of conductors 34 opposes the external electrode 14 in the first direction D1, and is disposed at a position overlapping the external electrode 14 when viewed from the first direction D1.

In the region R3, the conductor 34 is positioned in the same layer as the internal conductor 27. The conductor 34 is positioned in an opening formed in the internal conductor 27. The opening is formed at a position corresponding to the external electrode 14 when viewed from the first direction D1. The conductor 34 is surrounded by the internal conductor 27 when viewed from the first direction D1. The conductor 34 is separated from the internal conductor 27. The conductor 34 opposes the external electrode 14 in the first direction D1, and is disposed at a position overlapping the external electrode 14 when viewed from the first direction D1.

In the region R1, the plurality of through-hole conductors 44 include a through-hole conductor 44 positioned between the external electrode 14 and the conductor 34 adjacent to the external electrode 14, and a through-hole conductor 44 positioned between the internal electrode 21 and the conductor 34 adjacent to each other. A corresponding through-hole conductor 44 of the plurality of through-hole conductors 44 is positioned between the external electrode 14 and a layer including the internal electrode 25 closest to the main surface 11a. Another corresponding through-hole conductor 44 of the plurality of through-hole conductors 44 is positioned between a layer including the internal electrode 25 and a layer including the internal electrode 21. Each of the plurality of through-hole conductors 44 is disposed at a position overlapping the external electrode 14 when viewed from the first direction D1, and penetrates a corresponding piezoelectric layer 17 of the plurality of piezoelectric layers 17 in the first direction D1. In the region R1, the plurality of through-hole conductors 44 electrically connect the conductors 34 included in the region R1 and the internal electrodes 21 included in the region R1 to the external electrode 14.

In the region R2, the plurality of through-hole conductors 44 include a through-hole conductor 44 positioned between the conductors 34 adjacent to each other. A corresponding through-hole conductor 44 of the plurality of through-hole conductors 44 is positioned between a layer including the internal electrode 25 and a layer including the internal electrode 23. Each of the plurality of through-hole conductors 44 is disposed at a position overlapping the external electrode 14 when viewed from the first direction D1, and penetrates a corresponding piezoelectric layer 17 of the plurality of piezoelectric layers 17 in the first direction D1. In the region R2, the plurality of through-hole conductors 44 electrically connect the conductors 34 included in the region R2.

In the region R3, the plurality of through-hole conductors 44 include a through-hole conductor 44 positioned between the conductors 34 adjacent to each other. A corresponding through-hole conductor 44 of the plurality of through-hole conductors 44 is positioned between a layer including the internal electrode 25, among the internal electrode group 20, closest to the region R2 and a layer including the internal conductors 27. Another corresponding through-hole conductor 44 of the plurality of through-hole conductors 44 is positioned between a layer including the internal electrode 25, among the internal electrode group 22, closest to the R1 and the layer including the internal conductor 27. Each of the plurality of through-hole conductors 44 is disposed at a position overlapping the external electrode 14 when viewed from the first direction D1, and penetrates a corresponding piezoelectric layer 19 of the plurality of piezoelectric layers 19 in the first direction D1. In the region R3, the plurality of through-hole conductors 44 electrically connect the conductor 34 included in the region R3 and the conductors 34 included in the regions R1 and R2.

The internal electrodes 23 disposed in the region R2 are electrically connected to the external electrodes 13 via the connection conductor 30. The connection conductor 30 includes a plurality of conductors 33 and a plurality of through-hole conductors 43.

In the region R1, each of the plurality of conductors 33 is positioned in the same layer as a corresponding internal electrode 21 of the plurality of internal electrodes 21 or a corresponding internal electrode 25 of the plurality of internal electrodes 25. Each of the plurality of conductors 33 is positioned in an opening formed in the corresponding internal electrode 21 or an opening formed in the corresponding internal electrode 25. Each opening is formed at a position corresponding to the external electrode 13 when viewed from the first direction D1. Each of the plurality of conductors 33 is surrounded by the corresponding internal electrode 21 or the corresponding internal electrode 25 when viewed from the first direction D1. Each of the plurality of conductors 33 is separated from the corresponding internal electrode 21 or the corresponding internal electrode 25. Each of the plurality of conductors 33 opposes the external electrode 13 in the first direction D1, and is disposed at a position overlapping the external electrode 13 when viewed from the first direction D1.

In the region R2, each of the plurality of conductors 33 is positioned in the same layer as a corresponding internal electrode 25 of the plurality of internal electrodes 25. Each of the plurality of conductors 33 is positioned in an opening formed in the corresponding internal electrode 25. Each opening is formed at a position corresponding to the external electrode 13 when viewed from the first direction D1. Each of the plurality of conductors 33 is surrounded by the corresponding internal electrode 25 when viewed from the first direction D1. Each of the plurality of conductors 33 is separated from the corresponding internal electrode 25. Each of the plurality of conductors 33 opposes the external electrode 13 in the first direction D1, and is disposed at a position overlapping the external electrode 13 when viewed from the first direction D1. Each of the plurality of conductors 33 opposes a corresponding internal electrode 23 of the plurality of internal electrodes 23 in the first direction D1, and is disposed at a position overlapping the internal electrodes 23 when viewed from the first direction D1.

In the region R3, the conductor 33 is positioned in the same layer as the internal conductor 27. The conductor 33 is positioned in an opening formed in the internal conductor 27. The opening is formed at a position corresponding to the external electrode 13 when viewed from the first direction D1. The conductor 33 is surrounded by the internal conductor 27 when viewed from the first direction D1. The conductor 33 is separated from the internal conductor 27. The conductor 33 opposes the external electrode 13 in the first direction D1, and is disposed at a position overlapping the external electrode 13 when viewed from the first direction D1. For example, the conductor 33 and the conductor 34 that are positioned in the same layer as the internal conductor 27 are positioned in the same opening. The conductor 33 and the conductor 34 that are positioned in the same layer as the internal conductor 27 are adjacent to each other in the same opening. In each of the regions R1 and R2, for example, the conductors 33 and 34 that are positioned in the same layer as the internal electrodes 25 are positioned in the same opening. The conductor 33 and the conductor 34 that are positioned in the same layer as the internal electrode 25 are adjacent to each other in the same opening.

In the region R1, the plurality of through-hole conductors 43 include a through-hole conductor 43 positioned between the external electrode 13 and the conductor 33 adjacent to the external electrode 13, and a through-hole conductor 43 positioned between the conductors 33 adjacent to each other. A corresponding through-hole conductor 43 of the plurality of through-hole conductors 43 is positioned between the external electrode 13 and a layer including the internal electrode 25 closest to the main surface 11a. Another corresponding through-hole conductor 43 of the plurality of through-hole conductors 43 is positioned between a layer including the internal electrode 25 and a layer including the internal electrode 21. Each of the plurality of through-hole conductors 43 is disposed at a position overlapping the external electrode 13 when viewed from the first direction D1, and penetrates a corresponding piezoelectric layer 17 of the plurality of piezoelectric layers 17 in the first direction D1. In the region R1, the plurality of through-hole conductors 43 electrically connect the conductors 33 included in the region R1 to the external electrode 13.

In the region R2, the plurality of through-hole conductors 43 include a through-hole conductor 43 positioned between the internal electrode 23 and the conductor 33 adjacent to each other. A corresponding through-hole conductor 43 of the plurality of through-hole conductors 43 is positioned between a layer including the internal electrode 25 and a layer including the internal electrode 23. Each of the plurality of through-hole conductors 43 is disposed at a position overlapping the external electrode 13 when viewed from the first direction D1, and penetrates a corresponding piezoelectric layer 17 of the plurality of piezoelectric layers 17 in the first direction D1. In the region R2, the plurality of through-hole conductors 43 electrically connect the conductors 33 included in the region R2 and the internal electrodes 23 included in the region R2.

In the region R3, the plurality of through-hole conductors 43 include a through-hole conductor 43 positioned between the conductors 34 adjacent to each other. A corresponding through-hole conductor 43 of the plurality of through-hole conductors 43 is positioned between a layer including the internal electrode 25, among the internal electrode group 20, closest to the region R2 and a layer including the internal conductors 27. Another corresponding through-hole conductor 43 of the plurality of through-hole conductors 43 is positioned between a layer including the internal electrode 25, among the internal electrode group 22, closest to the R1 and the layer including the internal conductor 27. Each of the plurality of through-hole conductors 43 is disposed at a position overlapping the external electrode 13 when viewed from the first direction D1, and penetrates a corresponding piezoelectric layer 19 of the plurality of piezoelectric layers 19 in the first direction D1. In the region R3, the plurality of through-hole conductors 43 electrically connect the conductor 33 included in the region R3 and the conductors 33 included in the regions R1 and R2.

The internal electrodes 25 disposed in the regions R1 and R2 are electrically connected to the external electrodes 15 via the connection conductor 32. The connection conductor 32 includes a plurality of conductors 35 and a plurality of through-hole conductors 45.

Each of the plurality of conductors 35 is positioned in the same layer as a corresponding internal electrode 21 of the plurality of internal electrodes 21 or a corresponding internal electrode 23 of the plurality of internal electrodes 23. Each of the plurality of conductors 35 is positioned in an opening formed in the corresponding internal electrode 21 or an opening formed in the corresponding internal electrode 23. Each opening is formed at a position corresponding to the external electrode 15 when viewed from the first direction D1. Each of the plurality of conductors 35 is surrounded by the corresponding internal electrode 21 or the corresponding internal electrode 23 when viewed from the first direction D1. Each of the plurality of conductors 35 is separated from the corresponding internal electrode 21 or the corresponding internal electrode 23. Each of the plurality of conductors 35 opposes the external electrode 15 in the first direction D1, and is disposed at a position overlapping the external electrode 15 when viewed from the first direction D1. Each of the plurality of conductors 35 opposes a corresponding internal electrode 25 of the plurality of internal electrodes 25 in the first direction D1, and is disposed at a position overlapping the internal electrodes 25 when viewed from the first direction D1.

In the region R1, each of the plurality of conductors 35 is positioned in the same layer as the corresponding internal electrode 21. Each of the plurality of conductors 35 is positioned in the opening formed in the corresponding internal electrode 21. Each opening is formed at the position corresponding to the external electrode 15 when viewed from the first direction D1. Each of the plurality of conductors 35 is surrounded by the corresponding internal electrode 21 when viewed from the first direction D1. Each of the plurality of conductors 35 is separated from the corresponding internal electrode 21. Each of the plurality of conductors 35 opposes the external electrode 15 in the first direction D1, and is disposed at the position overlapping the external electrode 15 when viewed from the first direction D1.

In the region R2, each of the plurality of conductors 35 is positioned in the same layer as the corresponding internal electrode 23. Each of the plurality of conductors 35 is positioned in the opening formed in the corresponding internal electrode 23. Each opening is formed at the position corresponding to the external electrode 15 when viewed from the first direction D1. Each of the plurality of conductors 35 is surrounded by the corresponding internal electrode 23 when viewed from the first direction D1. Each of the plurality of conductors 35 is separated from the corresponding internal electrode 23. Each of the plurality of conductors 35 opposes the external electrode 15 in the first direction D1, and is disposed at the position overlapping the external electrode 15 when viewed from the first direction D1. Each of the plurality of conductors 35 opposes the corresponding internal electrode 25 in the first direction D1, and is disposed at the position overlapping the corresponding internal electrode 25 when viewed from the first direction D1.

In the region R3, the conductor 35 is positioned in the same layer as the internal conductor 27. The conductor 35 is positioned in an opening formed in the internal conductor 27. The opening is formed at a position corresponding to the external electrode 15 when viewed from the first direction D1. The conductor 35 is surrounded by the internal conductor 27 when viewed from the first direction D1. The conductor 35 is separated from the internal conductor 27. The conductor 35 opposes the external electrode 15 in the first direction D1, and is disposed at a position overlapping the external electrode 15 when viewed from the first direction D1.

In the region R1, the plurality of through-hole conductors 45 include a through-hole conductor 45 positioned between the external electrode 15 and the internal electrode 25 adjacent to the external electrode 15, and a through-hole conductor 45 positioned between the internal electrode 25 and the conductor 35 adjacent to each other. A corresponding through-hole conductor 45 of the plurality of through-hole conductors 45 is positioned between the external electrode 15 and a layer including the internal electrode 25 closest to the main surface 11a. Another corresponding through-hole conductor 45 of the plurality of through-hole conductors 45 is positioned between a layer including the internal electrode 25 and a layer including the internal electrode 21. Each of the plurality of through-hole conductors 45 is disposed at a position overlapping the external electrode 15 when viewed from the first direction D1, and penetrates a corresponding piezoelectric layer 17 of the plurality of piezoelectric layers 17 in the first direction D1. In the region R1, the plurality of through-hole conductors 45 electrically connect the conductors 35 included in the region R1 and the internal electrodes 25 included in the region R1 to the external electrode 15.

In the region R2, the plurality of through-hole conductors 45 include a through-hole conductor 45 positioned between the internal electrode 25 and the conductor 35 adjacent to each other. A corresponding through-hole conductor 45 of the plurality of through-hole conductors 45 is positioned between a layer including the internal electrode 25 and a layer including the internal electrode 23. Each of the plurality of through-hole conductors 45 is disposed at a position overlapping the external electrode 15 when viewed from the first direction D1, and penetrates a corresponding piezoelectric layer 17 of the plurality of piezoelectric layers 17 in the first direction D1. In the region R2, the plurality of through-hole conductors 45 electrically connect the conductors 35 included in the region R2 and the internal electrodes 25 included in the region R2.

In the region R3, the plurality of through-hole conductors 45 include a through-hole conductor 45 positioned between the internal electrode 25, among the internal electrode group 20, closest to the region R2 and the conductor 35, and a through-hole conductor 45 positioned between the internal electrode 25, among the internal electrode group 22, closest to the region R1 and the conductor 35. A corresponding through-hole conductor 45 of the plurality of through-hole conductors 45 is positioned between a layer including the internal electrode 25, among the internal electrode group 20, closest to the region R2 and a layer including the internal conductors 27. Another corresponding through-hole conductor 45 of the plurality of through-hole conductors 45 is positioned between a layer including the internal electrode 25, among the internal electrode group 22, closest to the R1 and the layer including the internal conductor 27. Each of the plurality of through-hole conductors 45 is disposed at a position overlapping the external electrode 15 when viewed from the first direction D1, and penetrates a corresponding piezoelectric layer 19 of the plurality of piezoelectric layers 19 in the first direction D1. In the region R3, the plurality of through-hole conductors 45 electrically connect the conductor 35 included in the region R3 and the internal electrodes 25 included in the regions R1 and R2.

The conductors 33, 34, and 35 included in the connection conductors 30, 31, and 32 have a rectangular shape. The conductors 33, 34, and 35 have, for example, a rectangular shape in which corners are rounded. The conductors 33, 34, and 35 included in the connection conductors 30, 31, and 32 may have a square shape.

The connection conductors 30, 31, and 32 include an electrically conductive material. The electrically conductive material includes, for example, Ag, Pd, Pt, or an Ag—Pd alloy. The connection conductors 30, 31, and 32 are configured, for example, as a sintered body of electrically conductive paste containing the electrically conductive material. The through-hole conductors 43, 44, and 45 are formed through sintering the electrically conductive paste filled in through-holes formed in the ceramic green sheets for forming the corresponding piezoelectric layers 17 and 19. The internal electrodes 21, 23, and 25 may include the electrically conductive material described above. The internal electrodes 21, 23, and 25 are configured, for example, as a sintered body of electrically conductive paste containing the electrically conductive material.

The region R1 includes a region positioned between the plurality of internal electrodes 21 and 25 opposing each other. The region R2 includes a region positioned between the plurality of internal electrodes 23 and 25 opposing each other. Hereinafter, a region located between the plurality of internal electrodes opposing each other may be referred to as an “inter-electrode region”.

The inter-electrode region included in the region R1 includes regions, of the plurality of piezoelectric layers 17 included in the region R1, positioned between the internal electrodes 21 and 25 that oppose each other. The inter-electrode region included in the region R1 includes an active region configured to be piezoelectrically active. The inter-electrode region included in the region R2 includes regions, of the plurality of piezoelectric layers 17 included in the region R2, positioned between the internal electrodes 23 and 25 that oppose each other. The inter-electrode region included in the region R2 includes an active region configured to be piezoelectrically active.

The active region included in the region R1 and the active region included in the region R2 are positioned between the main surface 11a and the main surface 11b. Each of the active region included in the region R1 and the active region included in the region R2 includes at least one piezoelectric layer 17. The active region included in the region R1 is positioned closer to the main surface 11a than the active region included in the region R2. The active region included in the region R2 is positioned closer to the main surface 11b than the active region included in the region R1. The region R3 is positioned between the active region included in the region R1 and the active region included in the region R1. For example, the region R3 includes an inactive configured to be piezoelectrically inactive.

For example, the active regions included in the regions R1 and R2 are positioned to surround the plurality of external electrodes 13, 14, and 15 when viewed from the first direction D1. The active regions included in the regions R1 and R2 include a region positioned between the external electrode 14 and the external electrode 15 when viewed from the first direction D1 and a region outside a region where the external electrodes 13, 14, and 15 are positioned when viewed from the first direction D1.

When driving the piezoelectric element 10, electrical voltages having different polarities are applied to the external electrodes 13 and 14. The electrical voltages applied to the external electrodes 13 and 14 are not applied to the external electrode 15. The external electrode 15 includes a ground electrode.

When applying the electrical voltage to the external electrode 14, an electric field is generated between the internal electrode 21 and the internal electrode 25 that oppose each other. The electric field is generated in the region R1, and the active region included in the region R1 is displaced in response to the electric field. When applying the electrical voltage to the external electrode 13, an electric field is generated between the internal electrode 23 and the internal electrode 25 that oppose each other. The electric field is generated in the region R2, and the active region included in the region R2 is displaced in response to the electric field. The regions R1 and R2 are displaced, for example, in opposite directions relative to each other. When the regions R1 and R2 are displaced in opposite directions relative to each other, the active region included in the region R1 and the active region included in the region R2 are displaced in opposite directions relative to each other in the first direction D1. When the electrical voltages are applied to the external electrodes 13 and 14, the piezoelectric element 10 is bend.

A configuration of the vibration member 50 will be described with reference to FIG. 1. The vibration member 50 is bonded to the main surface 11b of the piezoelectric body 11. The vibration member 50 includes main surfaces 50a and 50b opposing each other. The piezoelectric element 10 is disposed on the main surface 50a. For example, the vibration member 50 includes a plate-shaped member. The vibration member 50 includes, for example, a metal. The vibration member 50 includes, for example, a Ni—Fe alloy, glass, resin, or stainless steel. The vibration member 50 has a rectangular shape when viewed from the first direction D1. The rectangular shape includes, for example, a rectangular shape in which corners are chamfered or a rectangular shape in which corners are rounded.

A length of the vibration member 50 in the first direction D1 is, for example, 0.1 to 2 mm. A length of the vibration member 50 in the second direction D2 is, for example, 10 to 75 mm. A length of the vibration member 50 in the third direction D3 is, for example, 10 to 75 mm. In the vibration member 50, for example, the second direction D2 includes a longitudinal direction.

The vibration member 50 is bonded to the piezoelectric element 10 by, for example, a resin layer. The main surface 11b of the piezoelectric body 11 and the main surface 50a of the vibration member 50 oppose each other. The resin layer is positioned between the main surface 11b and the main surface 50a. The main surface 11b and the main surface 50a are bonded by the resin layer. In a configuration in which the piezoelectric element 10 is bonded to the vibration member 50, the main surface 50a and the main surface 50b oppose each other in the first direction D1. When viewed from the first direction D1, the piezoelectric element 10 is disposed, for example, in a central region of the main surface 50a. The resin layer includes, for example, an epoxy resin or an acrylic resin. The resin layer, for example, includes no electrically conductive filler and has electrical insulation properties.

When applying AC voltages to the external electrodes 13 and 14, in the piezoelectric element 10, the active region included in the region R1 and the active region included in the region R2 repeat expansion and contraction in response to the frequency of the applied AC voltages. The active region included in the region R1 and the active region included in the region R2 expand and contract in opposite directions relative to each other, and the piezoelectric element 10 generates flexural vibration. The vibrating member 50 generates flexural vibration integrally with the piezoelectric element 10 in response to the flexural vibration of the piezoelectric element 10.

Next, a configuration of the wiring member 60 will be described. The wiring member 60 electrically connects the piezoelectric element 10 and an electronic device. The wiring member 60 includes a pair of ends, and one end of the pair of ends is bonded to the piezoelectric element 10. The wiring member 60 includes a base member 61 and a reinforcing member 62. A plurality of conductors are disposed on the base member 61, and the plurality of conductors are electrically connected to the external electrodes 13, 14, and 15 of the piezoelectric element 10 at the one end. The wiring member 60 includes, for example, a flexible printed circuit board (FPC) or a flexible flat cable (FFC). The wiring member 60 has a plate-like, sheet-like, or band-like shape. The other end of the pair of ends is bonded to the reinforcing member 62. In the wiring member 60, the other end is positioned opposite to the one end. The reinforcing member 62 includes an electrically insulating plate-like member. The reinforcing member 62 includes, for example, a polyimide resin. The electronic device includes, for example, a circuit board or an electronic component.

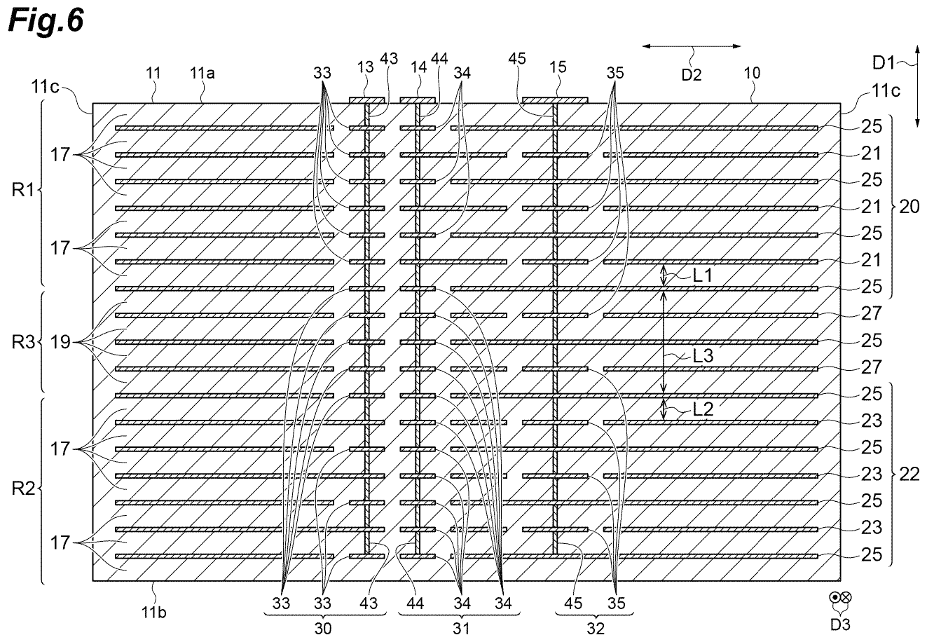

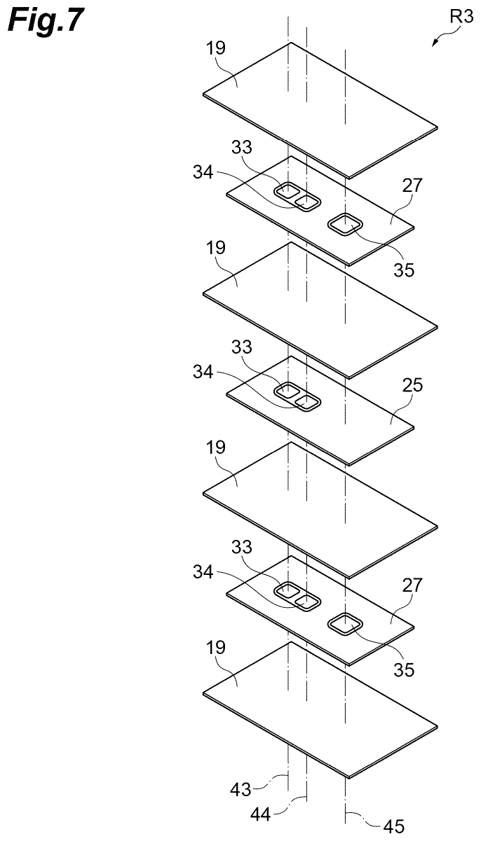

A configuration of a piezoelectric element 10 according to a modified example of the above-described example described above will be described with reference to FIGS. 6 and 7. FIG. 6 is a view illustrating a cross-sectional configuration of a piezoelectric element according to the modified example. FIG. 7 is an exploded perspective view illustrating the piezoelectric element according to the modified example.

The piezoelectric element 10 according to the modified example is generally similar to or the same as the piezoelectric element 10 according to the above-described example. However, the piezoelectric element 10 according to the modified example is different from the piezoelectric element 10 according to the above-described example in a configuration of region R3. Hereinafter, differences between the above-described example and the modified example will be mainly described. FIG. 7 illustrates the configuration of the region R3.

The region R1 in the modified example has the same configuration as the region R1 in the above-described example. That is, the region R1 in the modified example may include the configuration illustrated in FIG. 3. The region R2 in the modified example has the same configuration as the region R2 in the above-described example. That is, the region R2 in the modified example may include the configuration illustrated in FIG. 4. The region R3 in the modified example is different from the above-described example and includes, for example, four piezoelectric layers 19.

The internal electrode group 20 includes the plurality of internal electrodes 21 and 25. The internal electrodes 21 and the internal electrodes 25 oppose each other with the corresponding piezoelectric layer 17 interposed therebetween are separated by the distance L1. The internal electrode group 22 includes the plurality of internal electrodes 23 and 25. The internal electrodes 23 and the internal electrodes 25 oppose each other with the corresponding piezoelectric layer 17 interposed therebetween are separated by the distance L2.

The region R3 is positioned between the internal electrode 25, among the internal electrode group 20, closest to the region R2 and the internal electrode 25, among the internal electrode group 22, closest to the region R1. The region R3 includes a plurality of piezoelectric layers 19. The region R3 includes, for example, four piezoelectric layers 19. The piezoelectric layer 19 is positioned between the piezoelectric layers 17 included in the region R1 and the piezoelectric layers 17 included in the region R2. In the piezoelectric body 11, the plurality of piezoelectric layers 17 and 19 are laminated in the first direction D1. Each of the piezoelectric layers 19 has the same thickness.

In the modified example, the piezoelectric element 10 includes a plurality of internal conductors 27 in the region R3. The piezoelectric element 10 includes two internal conductors 27 unlike the above-described example. The piezoelectric element 10 includes an internal electrode 25 disposed between two internal conductors 27. The two internal conductors 27 and the internal electrode 25 between the two internal conductors 27 are disposed between the internal electrode 25, of the internal electrode group 20, closest to the region R2 and the internal electrode 25, of the internal electrode group 22, closest to the region R1. The two internal conductors 27 are disposed in the region R3. The internal electrode 25 closest to the region R2 and the internal electrode 25 closest to the region R1 are separated from each other by a distance L3 in the first direction D1. In the modified example, the distance L3 is larger than the distance L1 and the distance L2. The two internal conductors 27 are not electrically connected to the plurality of internal electrodes 21 and 25 included in the internal electrode group 20 and the plurality of internal electrodes 23 and 25 included in the internal electrode group 22. The two internal conductors 27 and the internal electrode 25 between the two internal conductors 27 are not exposed to the side surfaces 11c and 11e. The two internal conductors 27 and the internal electrode 25 between the two internal conductors 27 are separated from the side surfaces 11c and 11e.

In the region R3, the piezoelectric element 10 may not include the two internal conductors 27. In a configuration in which the piezoelectric element 10 may not include the two internal conductors 27, the distance L3 is larger than the distance L1 and the distance L2. In the region R3, the piezoelectric element 10 may not include the two internal conductors 27, but may include the internal electrodes 25. In a configuration in which the piezoelectric element 10 does not include the two internal conductors 27 but includes the internal electrodes 25, the distance L3 is larger than the distance L1 and the distance L2.

As described above, in the piezoelectric element 10, the internal electrode group 20 includes the plurality of internal electrodes 21 and 25 opposing each other in the region R1, and the region R1 includes the inter-electrode region. The internal electrode group 22 includes the plurality of internal electrodes 23 and 25 opposing each other in the region R2, and the region R2 includes the inter-electrode region. When applying electrical voltage, an electric field is generated in the inter-electrode region included in each of the regions R1 and R2, and the inter-electrode region included in each of the regions R1 and R2 can be displaced. In the piezoelectric element 10, the internal electrode 25 closest to the region R2 and the internal electrode 25 closest to the region R1 are electrically connected. Therefore, when applying the electrical voltage, the electric field tends to not be generated in the region positioned between the internal electrode 25 closest to the region R2 and the internal electrode 25 closest to the region R1, that is, the region R3, and the region R3 tends not to be displaced. When the inter-electrode region included in each of the regions R1 and R2 is displaced, stress may act on the region R2 due to displacement in the region R1, and stress may act on the region R1 due to displacement in the region R2. However, the region R3 reduces the stress acting on the region R2, and reduces the stress acting on the region R1. The piezoelectric element 10 can reduce stress generated in the piezoelectric body 11.

In the piezoelectric element 10, the plurality of internal electrodes 21 and 25 included in the internal electrode group 20 include the internal electrode 21 and the internal electrode 25 opposing the internal electrode 21. The plurality of internal electrodes 23 and 25 included in the internal electrode group 22 include the internal electrode 23 that is not electrically connected to the internal electrodes 21 and 25, and the internal electrode 25 opposing the internal electrode 23 and is electrically connected to the internal electrode 25 included in the internal electrode group 20. The internal electrode closest to the region R2 includes the internal electrode 25, and the internal electrode closest to the region R1 includes the internal electrode 25.

In the piezoelectric element 10, the internal electrode group 20 includes the internal electrode 21 and the internal electrode 25 opposing the internal electrode 21, and the internal electrode group 22 includes the internal electrode 23 not electrically connected to the internal electrodes 21 and 25 and the internal electrode 25 opposing the internal electrode 23. The internal electrode 25 closest to the region R2 is electrically connected to the internal electrode 25 closest to the region R1. Therefore, even in a configuration in which the internal electrode closest to the region R2 includes the internal electrode 25 opposing the internal electrode 21 and the internal electrode closest to the region R1 includes the internal electrode 25 opposing the internal electrode 23, the electric field tends not to be generated in the region R3 and the region R3 tends not to be displaced, when applying the electrical voltage. The region R3 reduces the stress acting on the region R2 due to the displacement of the region R1, and reduces the stress acting on the region R1 due to the displacement in the region R2. Consequently, the piezoelectric element 10 can reliably reduce the stress generated in the piezoelectric body 11.

The piezoelectric element 10 includes the internal conductor 27. The internal conductor 27 is disposed between the internal electrode 25 closest to the region R2 and the internal electrode 25 closest to the region R1, and is not electrically connected to the plurality of internal electrodes 21 and 25 included in the internal electrode group 20 and the plurality of internal electrodes 23 and 25 included in the internal electrode group 22.

The internal conductor 27 is disposed between the internal electrode 25 closest to the region R2 and the internal electrode 25 closest to the region R1, that is, in the region R3, and is not electrically connected to the plurality of internal electrodes 21, 23, and 25. Therefore, when applying the electrical voltage, the electric field further tends not to be generated in the region R3, and the region R3 further tends not to be displaced. The region R3 further reduces the stress acting on the region R2 due to the displacement of the region R1, and further reduces the stress acting on the region R1 due to the displacement of the region R2. Consequently, the piezoelectric element 10 can further reliably reduce the stress generated in the piezoelectric body 11.

In the piezoelectric element 10, the internal conductor 27 is not exposed to the side surfaces 11c and 11e.

In the piezoelectric element 10, the internal conductor 27 is covered with the piezoelectric body 11, and is disposed in the piezoelectric body 11. Therefore, the piezoelectric element 10 tends not to cause electrically short-circuited.

In the piezoelectric element 10, the distance L3 is larger than the distance L1 and the distance L2.

In the piezoelectric element 10, the distance between the region R1 and the region R2 is definitely large. The larger the distance between the regions R1 and R2, the more the stress acting on the region R2 due to the displacement in the region R1 and the stress acting on the region R1 due to the displacement in the region R2 are attenuated. Therefore, the piezoelectric element 10 can further reliably reduce the stress generated in the piezoelectric body 11.

In the piezoelectric element 10, the plurality of internal electrodes 21 and 25 included in the internal electrode group 20 and the plurality of internal electrodes 23 and 25 included in the internal electrode group 22 are not exposed to the side surfaces 11c and 11e.

In the piezoelectric element 10, the plurality of internal electrodes 21, 23, and 25 are covered with the piezoelectric body 11, and are disposed in the piezoelectric body 11. Therefore, the piezoelectric element 10 tends not to cause electrically short-circuited.

In the piezoelectric element 10, the regions R1 and R2 are displaced in opposite directions relative to each other.

The piezoelectric element 10 includes the plurality of external electrodes 13, 14, and 15. The external electrodes 13, 14, and 15 are disposed on the main surface 11a. Each of the external electrodes 13, 14, and 15 are electrically connected to the corresponding internal electrode 21, 23, or 25, among the plurality of internal electrodes 21 and 25 included in the internal electrode group 20 and the plurality of internal electrodes 23 and 25 included in the internal electrode group 22.

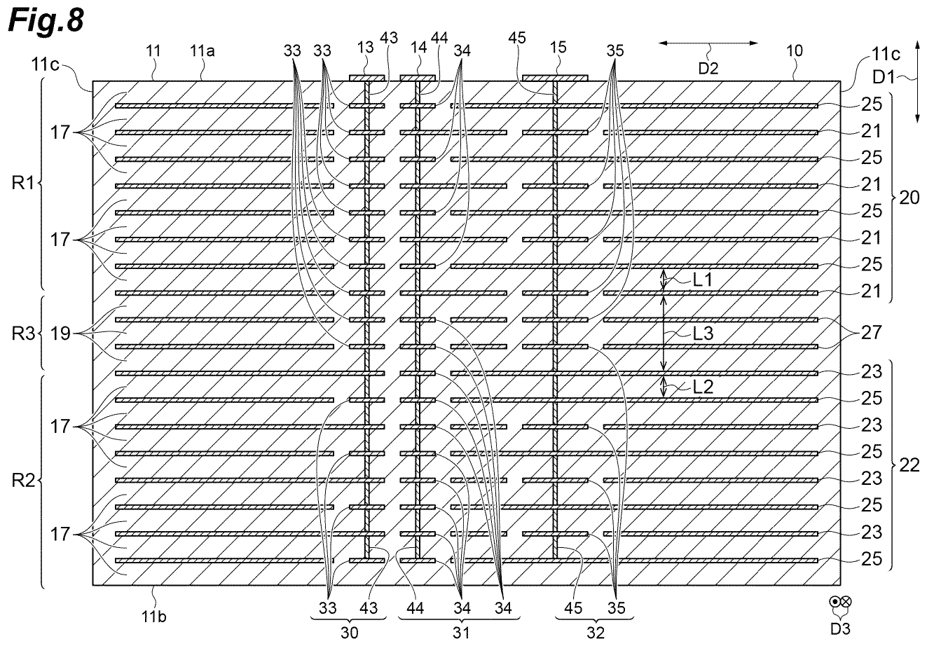

A configuration of a piezoelectric element 10 according to another example will be described with reference to FIG. 8. FIG. 8 is a view illustrating a cross-sectional configuration of a piezoelectric element according to the other example.

The piezoelectric element 10 according to the other example is generally similar to or the same as the piezoelectric element 10 according to the above-described example. However, the piezoelectric element 10 according to the other example is different from the piezoelectric element 10 according to the above-described example in a configuration between the region R1 and the region R3 and a configuration between the region R3 and the region R2. Hereinafter, differences between the above-described example and the other example will be mainly described.

The piezoelectric element 10 according to the other example includes the internal electrode group 20 and the internal electrode group 22.

The internal electrode group 20 is disposed in the region R1. The internal electrode group 20 includes the plurality of internal electrodes 21 and 25. The internal electrode 25 opposes the internal electrode 21. The internal electrode group 20 includes, for example, four internal electrodes 21 and four internal electrodes 25. The internal electrodes 21 and the internal electrodes 25 are alternately disposed, and the internal electrodes 21 and the internal electrodes 25 oppose each other with a corresponding piezoelectric layer 17 of the plurality of piezoelectric layers 17 interposed therebetween and are separated by a distance L1. The distances L1 between the internal electrodes 21 and the internal electrodes 25 are the same. The internal electrode group 20 includes an internal electrode 21 closest to the region R2 and an internal electrode 25 closest to the main surface 11a, among the plurality of internal electrodes 21 and 25.

The internal electrode group 22 is disposed in the region R2. The internal electrode group 22 includes the plurality of internal electrodes 23 and 25. The internal electrodes 23 are not electrically connected to the plurality of internal electrodes 21 and 25 included in the internal electrode group 20. The internal electrode 25 opposes the internal electrode 23. The internal electrode group 22 includes, for example, four internal electrodes 23 and four internal electrodes 25. The internal electrodes 23 and the internal electrodes 25 are alternately disposed, and the internal electrodes 23 and the internal electrodes 25 oppose each other with a corresponding piezoelectric layer 17 of the plurality of piezoelectric layers 17 interposed therebetween and are separated by a distance L2. The distances L2 between the internal electrodes 21 and the internal electrodes 25 are the same.

The internal electrode group 22 includes an internal electrode 23 closest to the region R1, among the plurality of internal electrodes 23 and 25 included in the internal electrode group 22. The internal electrode 23 closest to the region R1 and the internal electrode 21 closest to the region R2 are not electrically connected to each other. The internal electrode group 22 includes an internal electrode 25 closest to the main surface 11b, among the plurality of internal electrodes 23 and 25 included in the internal electrode group 22.

The region R3 is positioned between the internal electrode 21, among the internal electrode group 20, closest to the region R2 and the internal electrode 23, among the internal electrode group 22, closest to the region R1. The region R3 includes a plurality of piezoelectric layers 19. The region R3 includes, for example, four piezoelectric layers 19. The piezoelectric layer 19 is positioned between the piezoelectric layers 17 included in the region R1 and the piezoelectric layers 17 included in the region R2. In the piezoelectric body 11, the plurality of piezoelectric layers 17 and 19 are laminated in the first direction D1. Each of the piezoelectric layers 19 has the same thickness.

The piezoelectric element 10 according to the other example includes a plurality of internal conductors 27. The plurality of internal conductors 27 are disposed in the region R3. The piezoelectric element 10 includes, for example, two internal conductors 27. The two internal conductors 27 oppose each other, and are disposed between the internal electrode 21, of the internal electrode group 20, closest to the region R2 and the internal electrode 23, of the internal electrode group 22, closest to the region R1. The two internal conductors 27 are disposed in the region R3. The internal electrode 21 closest to the region R2 and the internal electrode 23 closest to the region R1 are separated from each other by a distance L3 in the first direction D1. The distance L3 is larger than the distance L1 and the distance L2. The two internal conductors 27 are not electrically connected to the plurality of internal electrodes 21 and 25 included in the internal electrode group 20 and the plurality of internal electrodes 23 and 25 included in the internal electrode group 22. The two internal conductors 27 are not exposed to the side surfaces 11c and 11e. The piezoelectric element 10 according to the other example may include one internal conductor 27. In a configuration in which the piezoelectric element 10 includes the one internal conductor 27, the distance L3 is larger than the distance L1 and the distance L2.

As described above, the piezoelectric element 10 according to the other example includes the piezoelectric body 11, the internal electrode group 20, and the internal electrode group 22, and the internal conductor 27. The piezoelectric body 11 includes the main surfaces 11a and 11b opposing each other and the side surfaces 11c and 11e coupling the main surfaces 11a and 11b. The piezoelectric body 11 includes the region R1 including the main surface 11a and the region R2 including the main surface 11b. The internal electrode group 20 is disposed in the region R1 and includes the plurality of internal electrodes 21 and 25 opposing each other in the direction in which the main surfaces 11a and 11b oppose each other. The internal electrode group 22 is disposed in the region R2 and includes the plurality of internal electrodes 23 and 25 opposing each other in the direction in which the main surfaces 11a and 11b oppose each other. The internal conductor 27 is disposed between the internal electrode 21, among the plurality of internal electrodes 21 and 25 included in the internal electrode group 20, closest to the region R2 and the internal electrode 23, among the plurality of internal electrodes 23 and 25 included in the internal electrode group 22, closest to the region R1, and is not electrically connected to the plurality of internal electrodes 21 and 25 included in the internal electrode group 20 and the plurality of internal electrodes 23 and 25 included in the internal electrode group 22.

In the piezoelectric element 10 according to the other example, the piezoelectric body 11 includes a region positioned between the internal electrode 21, among the plurality of internal electrodes 21 and 25 included in the internal electrode group 20, closest to the region R2 and the internal electrode 23, among the plurality of internal electrodes 23 and 25 included in the internal electrode group 22, closest to the region R1, that is, the region R3. The internal conductor 27 is disposed in the region R3, and is not electrically connected to the plurality of internal electrodes 21 and 25 included in the internal electrode group 20 and the plurality of internal electrodes 23 and 25 included in the internal electrode group 22. Therefore, when applying electrical voltage, an electric field tends to not be generated in the region R3. The region R3 tends not to be displaced. The region R3 reduces the stress acting on the region R2 due to the displacement of the region R1, and reduces the stress acting on the region R1 due to the displacement in the region R2. The piezoelectric element 10 according to the other example can reduce the stress generated in the piezoelectric body 11.

It is to be understood that not all aspects, advantages and features described herein may necessarily be achieved by, or included in, any one particular example. Indeed, having described and illustrated various examples herein, it should be apparent that other examples may be modified in arrangement and detail.

The internal conductor 27 may be exposed to either of the side surfaces 11c and 11e. However, in a configuration in which the internal conductor 27 is not exposed to the side surfaces 11c and 11e, as described above, this configuration tends not to cause electrically short-circuited.

The distance L3 may be smaller than the distance L1 and the distance L2. However, in a configuration in which the distance L3 is larger than the distance L1 and the distance L2, as described above, this configuration can further reliably reduce the stress generated in the piezoelectric body 11.

The plurality of internal electrodes 21, 23, and 25 may be exposed on any of the side surfaces 11c and 11e. However, in a configuration in which the internal electrode 21, 23, and 25 is not exposed to the side surfaces 11c and 11e, as described above, this configuration tends not to cause electrically short-circuited.

What is claimed is:

1. A piezoelectric element comprising:
a piezoelectric body including a first main surface and a second main surface opposing each other and a side surface coupling the first main surface and the second main surface, and including a first region including the first main surface and a second region including the second main surface;
a first internal electrode group disposed in the first region, and including a plurality of internal electrodes opposing each other in a direction in which the first main surface and the second main surface oppose each other; and
a second internal electrode group disposed in the second region, and including a plurality of internal electrodes opposing each other in a direction in which the first main surface and the second main surface oppose each other, wherein
an internal electrode, among the plurality of internal electrodes included in the first internal electrode group, closest to the second region and an internal electrode, among the plurality of internal electrodes included in the second internal electrode group, closest to the first region are electrically connected to each other.

2. The piezoelectric element according to claim 1, wherein
the plurality of internal electrodes included in the first internal electrode group include:
a first internal electrode; and
a second internal electrode opposing the first internal electrode,
the plurality of internal electrodes included in the second internal electrode group include:
a third internal electrode not electrically connected to the first internal electrode and the second internal electrode; and
a fourth internal electrode opposing the third internal electrode and electrically connected to the second internal electrode,
the internal electrode closest to the second region includes the second internal electrode, and
the internal electrode closest to the first region includes the fourth internal electrode.

3. The piezoelectric element according to claim 1, further comprising:
an internal conductor disposed between the internal electrode closest to the second region and the internal electrode closest to the first region, and not electrically connected to the plurality of internal electrodes included in the first internal electrode group and the plurality of internal electrodes included in the second internal electrode group.

4. The piezoelectric element according to claim 3, wherein
the internal conductor is not exposed to the side surface.

5. The piezoelectric element according to claim 1, wherein
a distance between the internal electrode closest to the second region and the internal electrode closest to the first region is larger than a distance between the plurality of internal electrodes included in the first internal electrode group and larger than a distance between the plurality of internal electrodes included in the second internal electrode group.

6. The piezoelectric element according to claim 1, wherein
the plurality of internal electrodes included in the first internal electrode group and the plurality of internal electrodes included in the second internal electrode group are not exposed to the side surface.

7. The piezoelectric element according to claim 1, wherein
the first region and the second region are configured to be displaced in opposite directions relative to each other.

8. The piezoelectric element according to claim 1, further comprising:
a plurality of external electrodes disposed on the first main surface, each of the plurality of external electrodes being electrically connected to a corresponding internal electrode among the plurality of internal electrodes included in the first internal electrode group and the plurality of internal electrodes included in the second internal electrode group.

9. A piezoelectric element comprising:
a piezoelectric body including a first main surface and a second main surface opposing each other and a side surface coupling the first main surface and the second main surface, and including a first region including the first main surface and a second region including the second main surface;
a first internal electrode group disposed in the first region, and including a plurality of internal electrodes opposing each other in a direction in which the first main surface and the second main surface oppose each other;
a second internal electrode group disposed in the second region, and including a plurality of internal electrodes opposing each other in a direction in which the first main surface and the second main surface oppose each other; and
an internal conductor disposed between an internal electrode, among the plurality of internal electrodes included in the first internal electrode group, closest to the second region and an internal electrode, among the plurality of internal electrodes included in the second internal electrode group, closest to the first region, the internal conductor being not electrically connected to the plurality of internal electrodes included in the first internal electrode group and the plurality of internal electrodes included in the second internal electrode group.

10. The piezoelectric element according to claim 9, wherein
the internal conductor is not exposed to the side surface.

11. The piezoelectric element according to claim 9, wherein
a distance between the internal electrode closest to the second region and the internal electrode closest to the first region is larger than a distance between the plurality of internal electrodes included in the first internal electrode group and larger than a distance between the plurality of internal electrodes included in the second internal electrode group.

12. The piezoelectric element according to claim 9, wherein
the plurality of internal electrodes included in the first internal electrode group and the plurality of internal electrodes included in the second internal electrode group are not exposed to the side surface.

13. The piezoelectric element according to claim 9, wherein
the first region and the second region are configured to be displaced in opposite directions relative to each other.

14. The piezoelectric element according to claim 9, further comprising:
a plurality of external electrodes disposed on the first main surface, each of the plurality of external electrodes being electrically connected to a corresponding internal electrode among the plurality of internal electrodes included in the first internal electrode group and the plurality of internal electrodes included in the second internal electrode group.
